(19) United States
(12) Patent Application Publication
(10) Pub. No.: US 2004/0045594 A1
(43) Pub. Date: Mar. 11, 2004

(54) Turbine engine with thermoelectric waste heat recovery system

(75) Inventor: Adrian Hightower, Pasadena, CA (US)

Correspondence Address: ADRIAN HIGHTOWER, 120 S. SIERRA MADRE BOULEVARD #304, PASADENA, CA, 91107, US

(73) Assignee: ENHANCED ENERGY SYSTEMS, INC.

(21) Appl. No.: 10/241,047

(22) Filed: Sep. 10, 2002

(51) Int. Cl. H01L 35/30

(52) U.S. Cl. 136/205; 52/173.1

(57) ABSTRACT

A turbine engine system includes a turbine engine that burns fuel and generates heat exhaust. A thermoelectric generator is located downstream from the turbine engine. The thermoelectric generator has a first side facing the heat exhaust. A cooling module is coupled to a second side of the thermoelectric generator to provide cooling to the second side. A pump is provided to pump a cooling fluid through the cooling module.

### BACKGROUND OF THE INVENTION

1. Technical Field

The present invention generally relates to turbine engines. More particularly, the present invention relates to turbine engines implementing thermoelectric generators to provide power by recovering waste heat exhaust generated by the turbine engine.

2. Discussion of the Related Art

Combustion turbine/generator systems are widely used for power generation. Combustion turbines, also known as gas turbine engines, are known to utilize fuel sources such as natural gas, petroleum, or finely divided, particulate material. Gas-fueled combustion turbine/generator systems have become a particularly attractive way of generating electrical energy because they may be more rapidly brought to an operational state than other types of generating systems.

FIG. 1 illustrates a conventional turbine engine generator. Gas turbine engines utilize the same basic technology as jet engines. The turbine engine generator includes an air intake side and a heat exhaust side. The turbine engine generator includes an electrical generator, a main shaft, a compressor, a fuel injector(s) within a combustion chamber, and turbine(s). Air is forced into the combustion chamber by the compressor, which is typically formed from a plurality of fan blades within a wheel. The fuel injector(s) provides fuel into the combustion chamber and the fuel is ignited. The turbine engine is capable of operating with a wide variety of fuels, including natural gas, gasoline, kerosene, and basically anything that burns. The hot combustion gases that form as a result of the combustion spin the turbine(s), which are also typically formed of fan blade-type structures within a wheel. The turbine(s) are connected to the main shaft, which is connected to the electrical generator. As the turbine(s) spins, the main shaft spins and operates the electrical generator to produce energy. The heat exhaust is expelled from the turbine engine generator into the atmosphere at the heat exhaust end of the turbine engine.

Typical power plants employing turbine engine generators achieve about 30-35% conversion rate for source energy to electricity. Some power plants utilize cogeneration, also known as combined heat and power, to heat water for the power plant by utilizing the waste heat exhaust from the turbine engine, for example, to increase the overall efficiency of energy production from the fuel spent. However, a turbine engine generator system that is capable of increasing the efficiency of the conversion rate for source energy to electricity, is needed.

### BRIEF DESCRIPTION OF THE DRAWINGS

FIG. 1 illustrates a turbine engine generator according to the prior art;

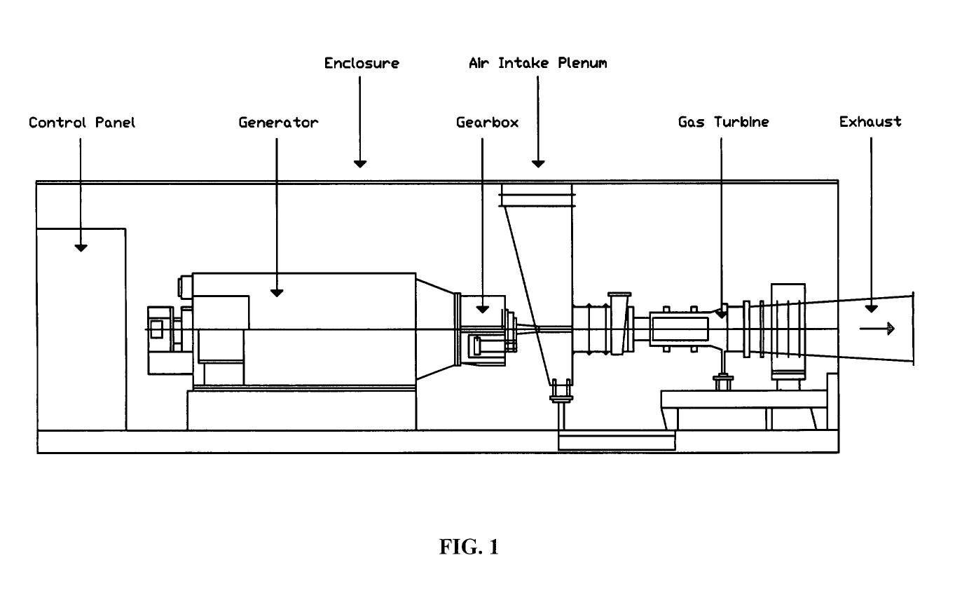

FIG. 2 illustrates a turbine engine system implementing a thermoelectric generator system according to an embodiment of the present invention;

FIG. 3 illustrates a flow chart diagram of constructing a turbine engine system according to an embodiment of the present invention;

FIG. 4 illustrates a turbine engine system implementing a thermoelectric generator system according to an alternative embodiment of the present invention; and

FIG. 5 illustrates a turbine engine system implementing a thermoelectric generator system according to another embodiment of the present invention.

### DETAILED DESCRIPTION

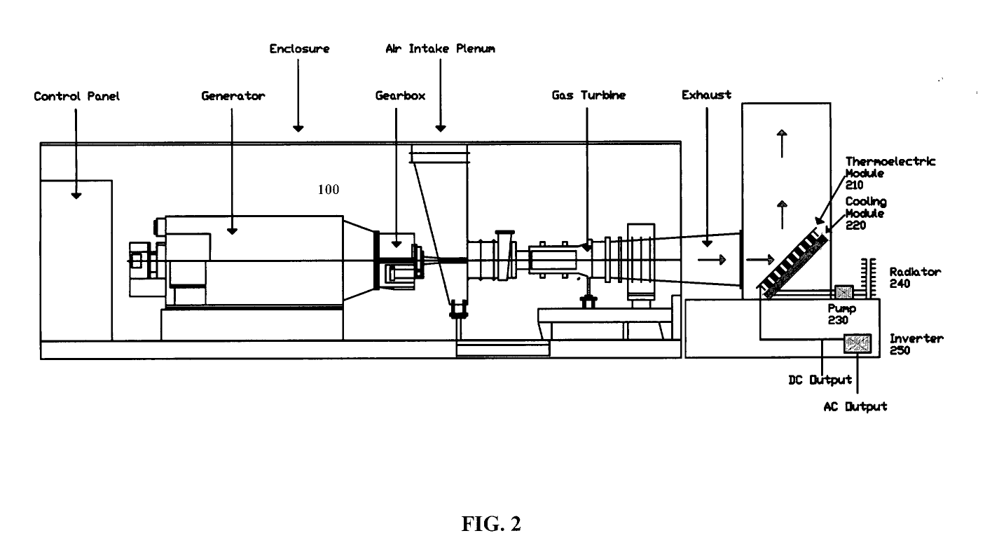

FIG. 2 illustrates a turbine engine system implementing a thermoelectric generator system according to an embodiment of the present invention. The turbine engine system 200 includes a turbine engine or turbine engine generator 100, a thermoelectric generator 210, a cooling module 220, and a pump 230. The turbine engine or turbine engine generator 100 burns fuel and generates heat exhaust. In one embodiment of the present invention, the turbine engine generator 100 is the primary power source. The thermoelectric generator 210 is located downstream from the turbine engine or turbine engine generator 100. According to an embodiment of the present invention, the thermoelectric generator 210 is located downstream from an exhaust end of the turbine engine or turbine engine generator 100.

A thermoelectric generator 210 converts heat into electricity with no moving parts. As heat moves past the thermoelectric generator 210, it causes an electrical current to flow. Thermoelectric generators 210 utilize a physics principle known as the Seebeck effect discovered in 1821. The Seebeck effect states that if two wires of different materials (such as copper and iron) are joined at their ends, forming two junctions, and one junction is held at a higher temperature than the other junction, a voltage difference will arise between the two junctions. Most thermoelectric devices currently in use today to generate electricity utilize semiconductor materials, such as bismuth telluride, which are good conductors of electricity but poor conductors of heat. These semiconductors are typically heavily doped to create an excess of electrons (n-type) or a deficiency of electrons (p-type). An n-type semiconductor develops a negative charge on the “cold” side and a p-type semiconductor will develop a positive charge on the “cold” side.

The thermoelectric generator 210 has a first side facing the heat exhaust expelled from the turbine engine or turbine engine generator 100 (i.e., the “hot side”). The thermoelectric generator 210 has a second side that faces away from the heat exhaust expelled from turbine engine or turbine engine generator 100 (the “cold side”). The cooling module 220 is coupled to the second side (“cold side”) of the thermoelectric generator 210 to provide cooling to the second side of the thermoelectric generator 210. By maximizing the temperature gradient across the “hot” side and the “cold” side of the thermoelectric generator 210 with the assistance of the cooling module 220, a greater amount of current may be generated. As illustrated in FIG. 2, the thermoelectric generator 210 may be configured at an angle to the flow of the heat exhaust, so as to deflect the heat exhaust.

A pump 230, in fluid communication with the cooling module 220, pumps a cooling fluid (e.g., water, anti-freeze coolant, cool/refrigerant air, etc.) through the cooling module 220. In one embodiment of the present invention, the cooling module 220 is formed from a plurality of cooling tubes or pipes. According to another embodiment of the present invention, a radiator 240 in fluid communication with the cooling module 220 is provided to radiate heat from the cooling fluid as it passes through the cooling module 220. Accordingly, by actively cooling the “cold” side of the thermoelectric generator 210 by utilizing a cooling module 220 with a pump 230, as compared to natural convection or passive air cooling with a heat sink, for example, a greater amount of current is generated due to the greater temperature gradient created between the “hot” side and the “cold” side of the thermoelectric generator 210.

Thermoelectric generators 210 typically produce a direct current (DC) power output. An inverter 250 may be utilized in electrical communication with the thermoelectric generator 210 to provide an alternating current (AC) power output.

According to one embodiment of the present invention, the turbine engine 100 is a gas turbine engine. As mentioned above, gas turbine engines are very versatile in the fuels it may utilize, which include propane, natural gas, kerosene, jet fuel, and anything that burns.

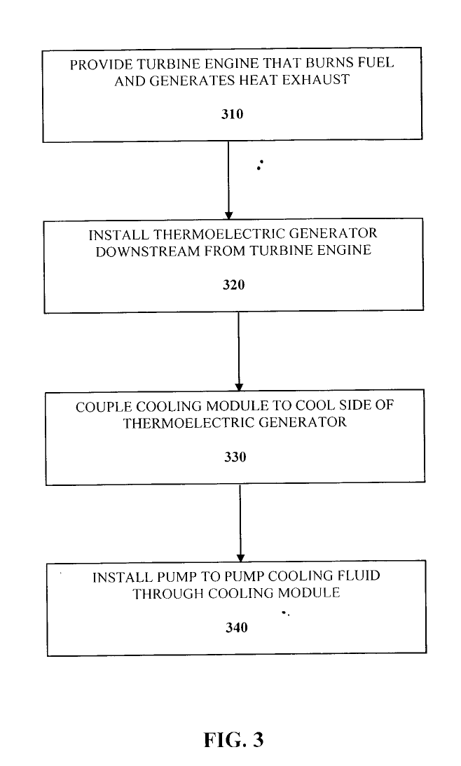

FIG. 3 illustrates a flow chart diagram of constructing a turbine engine system according to an embodiment of the present invention. A turbine engine or turbine engine generator 100 that burns fuel and generates heat exhaust is provided 310. A thermoelectric generator 210 is installed 320 downstream from the turbine engine or turbine engine generator 100. The thermoelectric generator 210 has a first side facing the heat exhaust expelled from the turbine engine or turbine engine generator 100. A cooling module 220 is coupled 330 to a second side (“cool” side) of the thermoelectric generator 210 to provided cooling to the second side of the thermoelectric generator 210. A pump 230 is installed 340 to pump a cooling fluid through the cooling module 220.

The turbine engine generator 100 may be a microturbine generator. Microturbine generators provide a distributed power generation solution for buildings and structures to generate electrical power locally on site. The microturbine generators may be utilized to augment a primary power source (e.g., as “backup power” in case of a black-out), or they may be configured for base loading, i.e., operation of on-site microturbine generators on a continuous basis (24 hours a day/7 days a week). Base loading is often utilized in regions with high electrical costs, or in cogeneration applications where the waste heat generated by the microturbine generator (or a “network” of microturbine generators) is recovered to heat (or cool) buildings, or to heat water. Accordingly, an on-site microturbine generator may be adapted to supply a facility with both electrical power and heated water. Microturbine generators achieve about 30% conversion rate for source energy to electricity. By utilizing a thermoelectric generator 210 with a cooling module 220 according to embodiments of the present invention, the conversion rate for source energy to electricity may be increased an additional 3-5%. This increase is significant, especially in microturbine generator applications, because microturbine generators are typically less efficient than larger generators. Moreover, the thermoelectric generator 210 with cooling module 220 requires less space than alternative waste heat recovery systems, as well as requiring lower installation and maintenance costs. Gas turbine engines with high-pressure ratios may utilize an intercooler to cool the air between the stages of compression, allowing the gas turbine engine to burn more fuel and generate more power. Intercoolers are typically large cooling towers with a sufficient heat sink to work along with the cooling module 220.

The thermoelectric generator 210 with a cooling module 220 may also be utilized with turbine engines 100 that primarily produce thrust (i.e., in jet aircraft), as opposed to producing torque for generating electricity, to provide an additional source of electricity for the aircraft or vehicle. Land-based vehicles utilizing turbine engines, such as tanks, may also benefit from the turbine engine system according to an embodiment of the present invention. Rather than placing the thermoelectric generator 210 directly behind the exhaust blast of the turbine engine in a jet aircraft, for example, the thermoelectric generator 210 and cooling module 220 may be placed on a side (or in a circumference) along the path of the exhaust blast.

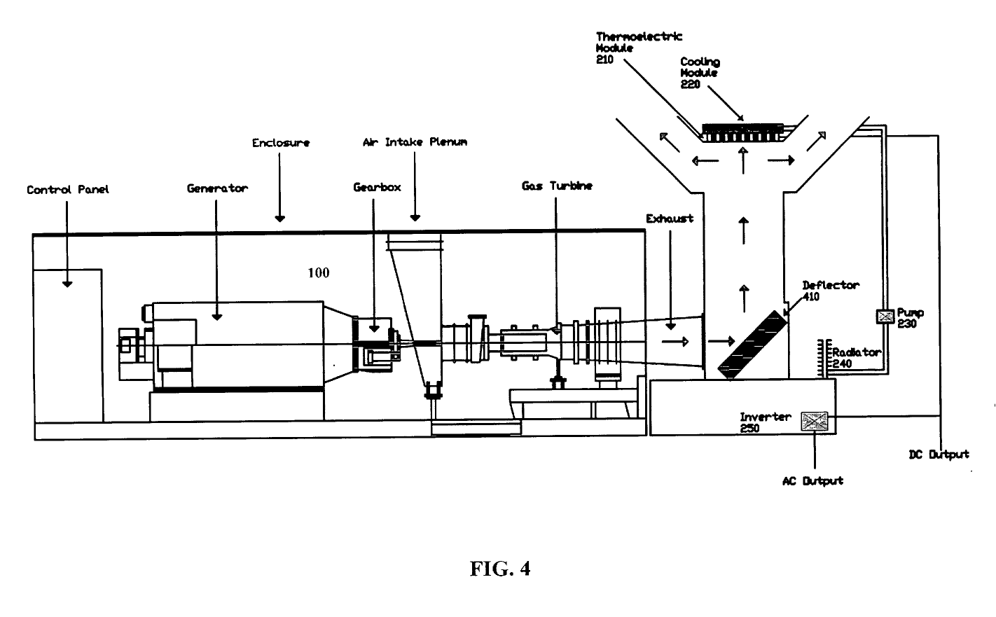

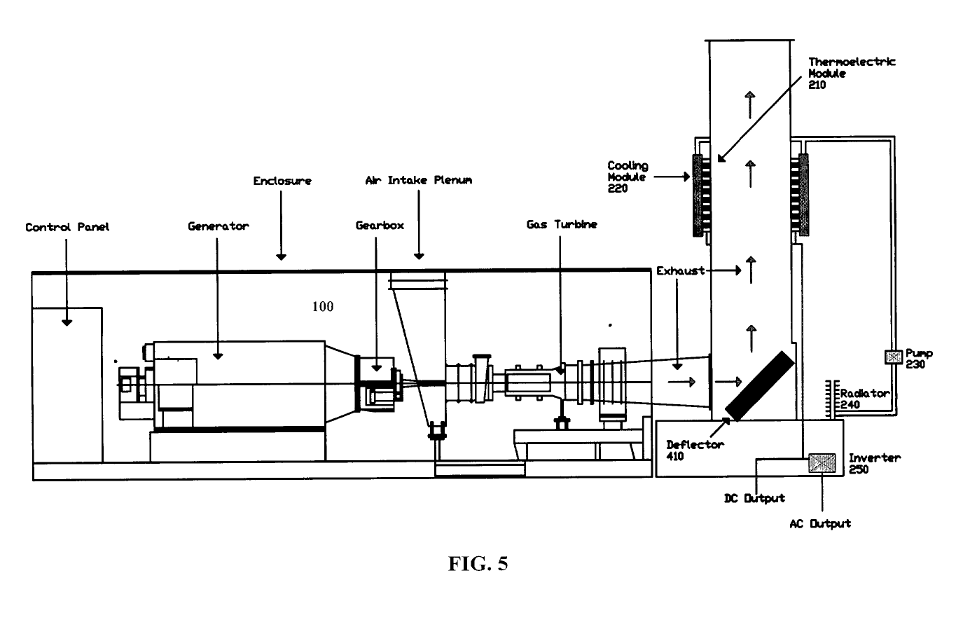

As illustrated in FIG. 4, the thermoelectric generator 210 may be located such that it receives and deflects heat exhaust expelled from the turbine engine or turbine engine generator 100 after the heat exhaust is first deflected by a deflector 410. FIG. 5 illustrates an alternative embodiment where the thermoelectric generator 210 is located on the sides of the exhaust stack along a length of a flow of the heat exhaust and facing the heat exhaust. The small size of the thermoelectric generator 210 allows it to be integrated with existing waste heat recovery systems. This integration is particularly useful in the embodiments illustrated in FIGS. 2, 4, and 5, where the exhaust path may be redirected to another waste heat recovery system(s). Alternative waste heat recovery systems may include boilers, water heating systems, secondary turbines, Sterling engines, closed Byton cycles, air pre-heaters, etc. Accordingly, any suitable configuration where the thermoelectric generator 210 faces the heat exhaust flow, e.g., head-on, at an angle, or along a length of the heat exhaust flow, etc., may be utilized.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are therefore intended to be embraced therein.

What is claimed is:

1. A turbine engine system, comprising:
a turbine engine that burns fuel and generates heat exhaust;
a thermoelectric generator located downstream from the turbine engine, wherein the thermoelectric generator has a first side facing the heat exhaust;
a cooling module coupled to a second side of the thermoelectric generator to provide cooling to the second side; and
a pump to pump a cooling fluid through the cooling module.

2. The turbine engine system according to claim 1, further including a radiator in fluid communication with the cooling module to radiate heat from the cooling fluid.

3. The turbine engine system according to claim 1, wherein the turbine engine system is a microturbine power generator.

4. The turbine engine system according to claim 1, wherein the turbine engine is a gas turbine engine.

5. The turbine engine system according to claim 1, wherein the fuel is at least one of propane, natural gas, kerosene, and jet fuel.

6. The turbine engine system according to claim 1, wherein the cooling module is formed from a plurality of cooling tubes.

7. The turbine engine system according to claim 1, wherein the thermoelectric generator includes an array of semiconductor elements.

8. The turbine engine system according to claim 1, further including an inverter in electrical communication with the thermoelectric generator to provide alternating current (AC) power.

9. The turbine engine system according to claim 1, wherein the thermoelectric generator is located along a length facing a flow of the heat exhaust.

10. A method of constructing a turbine engine system, comprising:
providing a turbine engine that burns fuel and generates heat exhaust;
installing a thermoelectric generator downstream the turbine engine, wherein the thermoelectric generator has a first side facing the heat exhaust;
coupling a cooling module to a second side of the thermoelectric generator to provide cooling to the second side; and
installing a pump to pump a cooling fluid through the cooling module.

11. The method according to claim 10, further including installing a radiator in fluid communication with the cooling module to radiate heat from the cooling fluid.

12. The method according to claim 10, wherein the turbine engine system is a microturbine power generator.

13. The method according to claim 10, wherein the turbine engine is a gas turbine engine.

14. The method according to claim 10, wherein the fuel is at least one of propane, natural gas, kerosene, and jet fuel.

15. The method according to claim 10, wherein the cooling module is formed from a plurality of cooling tubes.

16. The method according to claim 10, wherein the thermoelectric generator includes an array of semiconductor elements.

17. The method according to claim 10, further including installing an inverter in electrical communication with the thermoelectric generator to provide alternating current (AC) power.

18. A turbine engine system, comprising:
means for burning fuel and generating heat exhaust;
means for generating power located downstream from the means for burning fuel and generating heat exhaust, wherein the means for generating power has a first side facing the heat exhaust;
means for cooling a second side of the means for generating power coupled to the second side of the means for generating power; and
means for pumping a cooling fluid through the means for cooling.

19. The turbine engine system according to claim 18, further including means for radiating heat from the cooling fluid, in fluid communication with the means for cooling.

20. The turbine engine system according to claim 18, wherein the turbine engine system is a microturbine power generator.

21. The turbine engine system according to claim 18, wherein the means for burning fuel and generating heat exhaust is a gas turbine engine.

22. The turbine engine system according to claim 18, wherein the fuel is at least one of propane, natural gas, kerosene, and jet fuel.

23. The turbine engine system according to claim 18, wherein the means for cooling is formed from a plurality of cooling tubes.

24. The turbine engine system according to claim 18, wherein the means for generating power includes an array of semiconductor elements.

25. The turbine engine system according to claim 18, further including inverter means in electrical communication with the means for generating power for providing alternating current (AC) power.

26. The turbine engine system according to claim 18, wherein the means for generating power is located along a length facing a flow of the heat exhaust.

27. A building having an electrical power generation system, comprising:
a structure having a plurality of walls; and
a turbine engine generator system located adjacent to the structure, having
a turbine engine that burns fuel, generates heat exhaust, and provides a primary electrical power source,
a thermoelectric generator to provide a secondary electrical power source located downstream from the turbine engine, wherein the thermoelectric generator has a first side facing the heat exhaust,
a cooling module coupled to a second side of the thermoelectric generator to provide cooling to the second side, and
a pump to pump a cooling fluid through the cooling module.

28. The building according to claim 27, wherein the turbine engine generator system further includes a radiator in fluid communication with the cooling module to radiate heat from the cooling fluid.

29. The building according to claim 27, wherein the turbine engine generator system is a microturbine power generator.

30. The building according to claim 27, wherein the turbine engine is a gas turbine engine.

31. The building according to claim 27, wherein the fuel is at least one of propane, natural gas, kerosene, and jet fuel.

32. The building according to claim 27, wherein the cooling module is formed from a plurality of cooling tubes.

33. The building according to claim 27, wherein the thermoelectric generator includes an array of semiconductor elements.

34. The building according to claim 27, wherein the turbine engine generator system further includes an inverter in electrical communication with the thermoelectric generator to provide alternating current (AC) power.

35. The building according to claim 27, wherein the turbine engine generator system is located on a roof of the structure.
